(19) United States
(12) Patent Application Publication
(10) Pub. No.: US 2025/0379199 A1
(43) Pub. Date: Dec. 11, 2025

(54) MULTI-SENSOR PACKAGE STRUCTURE AND METHOD FOR FORMING THE SAME

(71) Applicant: JCET Group Co., LTD., Jiangyin (CN)

(72) Inventors: Shuo LIU, Jiangyin (CN); Jingcheng GE, Jiangyin (CN); Yaojian LIN, Jiangyin (CN); Hua ZONG, Jiangyin (CN); Kailun ZHANG, Jiangyin (CN)

(73) Assignee: JCET Group Co., LTD., Jiangyin (CN)

(21) Appl. No.: 19/233,250

(22) Filed: Jun. 10, 2025

(30) Foreign Application Priority Data
Jun. 11, 2024 (CN) 202410750357.5

(51) Int. Cl. H01L 25/16

(52) U.S. Cl. CPC H01L 25/167; H01L 25/165

(57) ABSTRACT

A multi-sensor package structure includes a substrate, an acoustic sensor, a first chip, and a second chip mounted on an upper surface of the substrate, a light sensor having a light window mounted on the second chip, the light sensor having a light window being electrically connected with the second chip, a first lead wire electrically connecting the acoustic sensor with the first chip, a second lead wire electrically connecting the first chip with the substrate, and a third lead wire electrically connecting the second chip with the substrate, and a sound shielding cover mounted on the upper surface of the substrate, the sound shielding cover covering the acoustic sensor and the first chip, the sound shielding cover having sound transmitting holes running through an inner sidewall surface and an outer sidewall surface of the sound shielding cover.

### CROSS-REFERENCE TO RELATED APPLICATIONS

This application claims the benefit of priority to Chinese Application No. 202410750357.5, filed on Jun. 11, 2024, which is hereby incorporated by reference in its entirety.

### TECHNICAL FIELD

The present disclosure relates to the field of semiconductor package, and particularly relates to a multi-sensor package structure and a method for forming the same.

### BACKGROUND

With the high-speed development of artificial intelligence, robotics, language processing, speech and image recognition, the Internet of Things (smart city), etc., in the future, the intensive integration of sensor technology and chip package technology are required to realize the conversion of different kinds of information captured into the corresponding electrical signals, so as to realize the Internet of Everything and facilitate human life.

### SUMMARY

The present disclosure provides at first a method for forming a multi-sensor package structure, the method comprising: providing a substrate, a first chip, a second chip, an acoustic sensor, and a light sensor having a light window; mounting the acoustic sensor, the first chip, and the second chip on an upper surface of the substrate, respectively; mounting the light sensor having a light window on the second chip, and the light sensor having a light window being electrically connected with the second chip; forming a first lead wire electrically connecting the acoustic sensor with the first chip, a second lead wire electrically connecting the first chip with the substrate, and a third lead wire electrically connecting the second chip with the substrate; providing a sound shielding cover, the sound shielding cover having sound transmission holes penetrating through an inner sidewall surface and an outer sidewall surface of the sound shielding cover; and mounting the sound shielding cover on the upper surface of the substrate, such that the sound shielding cover covers the acoustic sensor and the first chip.

Optionally, the acoustic sensor is used for sensing sound signals to generate electrical signals, the first chip is used for processing the electrical signal generated by the sensing of the acoustic sensor, the light sensor is used for sensing a light signal to generate an electrical signal, and the second chip is used for processing the electrical signal generated by the sensing of the light sensor.

Optionally, the acoustic sensor comprises an opposing back surface and a sound-sensing surface, the sound-sensing surface having a suspended sound-sensing film, the first chip and the second chip both comprising an opposing back surface and an active surface, respectively, and the back surface of the acoustic sensor, the back surface of the first chip, and the back surface of the second chip being mounted on an upper surface of the substrate by an adhesive glue, respectively.

Optionally, the light sensor comprises an opposing back surface and a light-sensing surface, the light-sensing surface comprising a middle area and an edge area surrounding the middle area, the middle area having a light-sensing area therein, the light window being mounted on the surface of the edge area of the light-sensing surface by a first sealant, and a sealed cavity is formed between the lower surface of the light window and the light-sensing surface.

Optionally, the first sealant is a filler-containing sealant; and the temperature of the base for securing the light sensor is heated to a temperature of 40 degrees Celsius to 50 degrees Celsius when the light window is mounted to the surface of the edge area by the first sealant.

Optionally, the upper and lower surfaces of the light window have a coating, and the area of the lower surface of the light window in contact with the first sealant is uncoated and said area is roughened by hacking.

Optionally, after forming the first lead wire, the second lead wire, and the third lead wire, a second sealant is formed that seals the side of the light sensor having a light window and the second chip, and a third sealant is formed that seals the first chip.

Optionally, after forming the first lead wire, the second lead wire, and the third lead wire, a third sealant is formed that seals the first chip; and the sound shielding cover is mounted on the upper surface of the substrate, an integral sealant is formed that seals the side of the light sensor having a light window, the second chip, and the side of the sound shielding cover.

Optionally, the sealed cavity is filled with nitrogen gas, and the pressure in the sealed cavity is 0.2 times to 1 times atmospheric pressure.

Optionally, the light window has at least one light window hole in the light window running through the upper and lower surfaces of the light window, the light window hole being in communication with the sealed cavity, and a fourth sealant is employed to seal the light window hole after forming the second sealant or after forming the integral sealant.

Optionally, the processes of sealing the light window hole with a fourth sealant comprise: placing the package structure in a processing chamber, evacuating the processing chamber; after evacuating, filling the processing chamber with nitrogen gas to adjust the air pressure of the processing chamber to 0.2 times to 1 times atmospheric pressure, and then dabbing a fourth sealant into the light window hole for sealing.

Another embodiment of the present disclosure also provides a multi-sensor package structure, the structure comprising: a substrate; an acoustic sensor, a first chip, and a second chip mounted on an upper surface of the substrate; a light sensor having a light window mounted on the second chip, the light sensor having a light window being electrically connected with the second chip; a first lead wire electrically connecting the acoustic sensor with the first chip, a second lead wire electrically connecting the first chip with the substrate, and a third lead wire electrically connecting the second chip with the substrate; and a sound shielding cover mounted on the upper surface of the substrate, the sound shielding cover covering the acoustic sensor and the first chip, the sound shielding cover having sound transmitting holes running through the inner sidewall surface and outer sidewall surface of the sound shielding cover.

Optionally, the acoustic sensor is used for sensing sound signals to generate electrical signals, the first chip is used for processing the electrical signals generated by the sensing of the acoustic sensor, the light sensor is used for sensing light signals to generate electrical signals, the second chip is used for processing the electrical signals generated by the sensing of the light sensor.

Optionally, the acoustic sensor comprises an opposing back surface and a sound-sensing surface, the sound-sensing surface having a suspended sound-sensing film, the first chip and the second chip both comprising an opposing back surface and an active surface, respectively, and the back surface of the acoustic sensor, the back surface of the first chip, and the back surface of the second chip being mounted on an upper surface of the substrate by an adhesive glue, respectively.

Optionally, the light sensor comprises an opposing back surface and a light-sensing surface, the light-sensing surface comprising a middle area and an edge area surrounding the middle area, the middle area having a light-sensing area therein, the light window being mounted on the surface of the edge area of the light-sensing surface by a first sealant, and a sealed cavity is formed between the lower surface of the light window and the light-sensing surface.

Optionally, the first sealant is a filler-containing sealant.

Optionally, the upper and lower surfaces of the light window have a coating, and the area of the lower surface of the light window in contact with the first sealant is uncoated and said area is roughened by hacking.

Optionally, it further comprises: a second sealant sealing the side of the light sensor having a light window and the second chip, and a third sealant sealing the first chip.

Optionally, it further comprises: a third sealant sealing the first chip; and an integral sealant sealing the sides of the light sensor having a light window, the second chip, and the sides of the sound shielding cover.

Optionally, the sealed cavity is filled with nitrogen gas, the sealed cavity being at a pressure of 0.2 times to 1 times atmospheric pressure.

Optionally, the light window has at least one light window hole in the light window running through the upper and lower surfaces of the light window, and a fourth sealant sealing the light window hole.

### BRIEF DESCRIPTION OF THE DRAWINGS

FIGS. 1-4 are schematic structural diagrams of the formation process of a multi-sensor package structure in an embodiment of the present disclosure;

FIGS. 5-7 are schematic structural diagrams of the formation process of the multi-sensor package structure in another embodiment of the present disclosure;

FIGS. 8-9 are schematic structural diagrams of the formation process of the multi-sensor package structure in yet another embodiment of the present disclosure; and

FIG. 10 is a flow chart of a method for forming a multi-sensor package structure in an embodiment of the present disclosure.

### DETAILED DESCRIPTIONS

Specific embodiments of the present disclosure are described in detail below in conjunction with the accompanying drawings. In detailing the embodiments of the present disclosure, the schematic diagrams will not be partially enlarged according to the general scale, for the convenience of illustration, and the schematic diagrams are only examples, which shall not limit the scope of protection of the present disclosure herein. In addition, the three-dimensional spatial dimensions of length, width, and depth should be included in the actual production.

The current sensor package structure is mostly a single-sensor structure, and there is an urgent need for a package structure that integrates multiple sensors, to cope with the exponentially growing demand for informatization. It is a problem to be solved by the present disclosure to provide a package structure for multi-sensor integration and a method for forming the same.

In order to solve the above problem, an embodiment of the present disclosure first provides a method for forming a multi-sensor package structure, and the process for forming a multi-sensor package structure is described in detail below in conjunction with the accompanying drawings.

The advantages of the technical solution of the present disclosure include the following.

The package structure and a method for forming the same of the present disclosure, the method for forming the same: after providing a substrate, a first chip, a second chip, an acoustic sensor, and a light sensor having a light window, mounting the acoustic sensor, the first chip, and the second chip on an upper surface of the substrate, respectively; mounting the light sensor having a light window on the second chip, and the light sensor having a light window being electrically connected with the second chip; forming a first lead wire electrically connecting the acoustic sensor with the first chip, a second lead wire electrically connecting the first chip with the substrate, and a third lead wire electrically connecting the second chip with the substrate; providing a sound shielding cover, the sound shielding cover having sound transmission holes penetrating through an inner sidewall surface and an outer sidewall surface of the sound shielding cover; and mounting the sound shielding cover on the upper surface of the substrate, such that the sound shielding cover covers the acoustic sensor and the first chip. The present disclosure realizes the integrated package of the light sensor and the acoustic sensor, and the light sensor has a light window, and the acoustic sensor has a sound shielding cover to prevent the interference of external signals to the light sensor and the acoustic sensor, and to improve the sensing accuracy of the light sensor and the acoustic sensor. In addition, when packaging, the first chip and the second chip are packaged together, and the first chip and the second chip can process the sensed electrical signals of the corresponding acoustic sensor and light sensor, thereby improving the performance of the package structure.

Furthermore, a sealed cavity is formed between the lower surface of the light window and the light-sensing surface of the light sensor, the sealed cavity is filled with nitrogen gas, and the pressure in the sealed cavity is 0.2 times to 1 times the atmospheric pressure, so that the sealed cavity is maintained in the aforementioned negative pressure environment of a specific value under nitrogen gas, on the one hand, the dryness of the sealed cavity is maintained to prevent the influence of excessive humidity on the detection accuracy of the light sensor, on the other hand, since a thermal process (such as a curing process or a reflow process) will exist in the subsequent package process, that the sealed cavity is maintained in the aforementioned negative pressure environment of a specific value under nitrogen gas can reduce the risk brought about by the expansion of the gas and improve the structural stability of the light sensor.

Furthermore, the function of the light window having at least one light window hole running through the upper surface and the lower surface of the light window is: on the one hand, the light window hole can discharge the expansion gas generated in the cavity between the light window and the light-sensing surface of the light sensor during the reflow process or the curing process, so as to prevent the expansion of the gas from affecting or damaging the structural stability of the light sensor; on the other hand, the light window hole can discharge volatile substances generated during the curing of the first sealant, preventing the volatile substances from remaining in the chamber and damaging the light sensor; on the other hand again, subsequently sealing the light window hole by the fourth sealant can still form a sealed cavity between the lower surface of the light window and the light-sensing surface of the light sensor, so that the sealed cavity is filled with nitrogen gas, and the pressure in the sealed cavity is 0.2 times to 1 times the atmospheric pressure, so as to maintain the dryness of the sealed cavity and preventing the influence of excessive humidity on the detection accuracy of the light sensor.

Furthermore, after forming the first lead wire, second lead wire, and third lead wire, a second sealant is formed that seals the side of the light sensor having a light window and the second chip to further improve the waterproof performance and sealing performance of the light window, and a third sealant is formed that seals the first chip to improve waterproofing performance of the acoustic sensor.

Furthermore, an integral sealant is formed that seals the sides of the light sensor having a light window, the second chip, and the sides of the sound shielding cover, thus enhancing the overall strength, air-tight performance, and waterproof performance of the package structure.

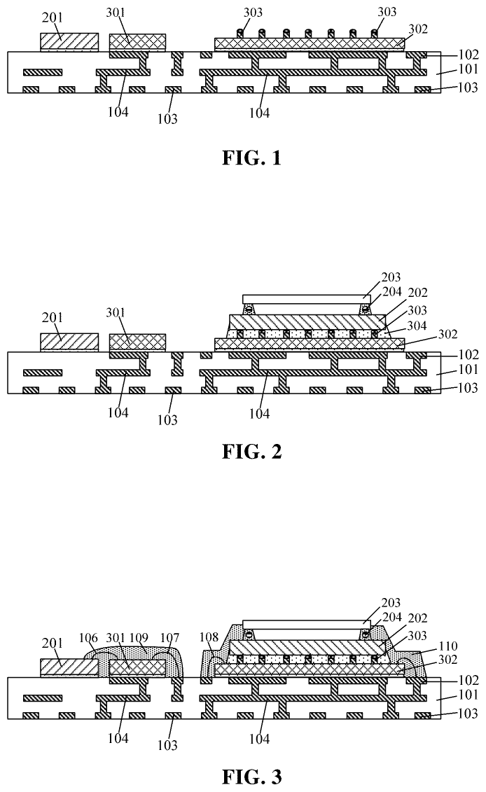

Referring to FIG. 1, a substrate 101, a first chip 301, a second chip 302, and an acoustic sensor 201 are provided; the acoustic sensor 201, the first chip 301, and the second chip 302 are mounted on an upper surface of the substrate 101, respectively.

The substrate 101 comprises an opposing upper surface and a lower surface, the upper surface of the substrate 101 having a number of upper pads 102, the lower surface of the substrate 101 having a number of lower pads 103, and the substrate 101 has a connection line 104 in it, the connection line 104 electrically connecting the upper pads 102 on the upper surface of the substrate 101 with corresponding lower pads 103 on the lower surface of the substrate 101. Some of the upper pads 102 on the upper surface of the substrate 101 are subsequently electrically connected with the first chip 301 and the second chip 302, and an external connection protrusion 105 can be subsequently formed on the lower pads 103 on the lower surface of the substrate 101 (referring to FIG. 4), and the external connection protrusion 105 is used to be connected with other devices or package structures. In an embodiment, the materials of the upper pads 102, the lower pads 103 and the connection line 104 are metals and may be one or more of aluminum, nickel, tin, tungsten, platinum, copper, titanium, chromium, tantalum, gold, silver. The material of the external connection protrusion 105 is one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony.

In an embodiment, the substrate 101 may be one of a resin substrate, a ceramic substrate, a glass substrate, a silicon substrate, a printed circuit board (PCB), or a flexible circuit board (FPC). The substrate 101 may be a single-layer board or a multi-layer board.

In an embodiment, the substrate 101 may comprise a number of package areas arranged in positive rows and columns and a cutting area located between adjacent package areas. On each package area, the same package process is subsequently performed (package of acoustic sensors, light sensors, and the first chip and the second chip is carried out), and after package is completed, the package structure completed by package is cut along the dicing lane, and a number of discrete multi-sensor package structures may be obtained.

The acoustic sensor 201 is used for sensing sound signals to generate electrical signals. The acoustic sensor 201 may be a MEMS acoustic sensor. In an embodiment, the acoustic sensor 201 comprises an opposing back surface and a sound-sensing surface, the sound-sensing surface having a suspended sound-sensing film, and the sound-sensing film sensing the vibration of a sound tone to generate an electrical signal. In an embodiment the sensed sound frequency being 20 Hz-20000 Hz, the sound-sensing surface also has an external connection pad electrically connected with the sound-sensing film, the external connection pad of the acoustic sensor 201 subsequently being electrically connected with the first chip 301 via a first lead wire. When the acoustic sensor 201 is mounted on the upper surface of the substrate 101, the back surface of the acoustic sensor 201 is mounted on the upper surface of the substrate 101. In an embodiment, the back surface of the acoustic sensor 201 can be mounted on the upper surface of the substrate 101 by an adhesive glue. The adhesive glue can be a glue or an adhesive film (Die Attach Film, DAF).

The first chip 301 is used to process the electrical signals sensed by the acoustic sensor 201, and the second chip 302 is used to process the electrical signals sensed by the subsequently mounted light sensor 202 (referring to FIG. 2).

The processing performed by the first chip 301 on the electrical signals sensed by the acoustic sensor 201 and the processing performed by the second chip 302 on the electrical signals sensed by the subsequently mounted light sensor 202 (referring to FIG. 2) comprise one or more of signal filtering, signal enhancement, feature extraction, data compression, and data analysis and pattern recognition.

Signal filtering is to remove the noise and interference in the electrical signals generated by the sensing in order to extract the real information of the signals. Commonly used signal filtering methods comprise low-pass filtering, high-pass filtering, band-pass filtering, etc., and the appropriate filtering algorithm can be selected according to the actual needs.

Signal enhancement is the signal enhancement of the electrical signals generated by sensing to improve the strength and reliability of the signals. Common signal enhancement methods comprise amplification, filtering gain control, etc., and these methods can effectively enhance the quality of signals.

Feature extraction can extract useful features related to the needed information from the electrical signals generated by sensing, for subsequent analysis and processing. Commonly used feature extraction methods comprise time domain feature extraction, frequency domain feature extraction, wavelet transform, etc.

Data compression compresses the electrical signals generated by sensing to save storage space and transmission bandwidth. Common data compression methods comprise lossless compression and lossy compression, and the appropriate compression algorithm is selected according to the application scenario.

Data analysis and pattern recognition is the process of analyzing and processing signals generated by sensing, and useful information and data may be obtained. In this process, a method for data analysis and pattern recognition needs to be applied in order to identify patterns and regularities in the signals to provide support for subsequent applications.

The first chip 301 and the second chip 302 both comprise an opposing back and an active surface, respectively. On the active surface of the first chip 301, there is a connection pad (not shown in the figures), the first chip 301 has an integrated circuit (not shown in the figures) with a specific function, the connection pad is electrically connected with the integrated circuit in the first chip 301, and the connection pad of the first chip 301 is subsequently electrically connected with the external connection pad of the acoustic sensor 201 via a first lead wire. On the active surface of the second chip 302, there is an external connection pad and a raised welding protrusion 303, the second chip 302 has an integrated circuit with a specific function in it (not shown in the figures), the external connection pad and the welding protrusion 303 are electrically connected with the integrated circuit in the second chip 302, and the welding protrusion 303 on the second chip 302 is subsequently also electrically connected with a light sensor. In an embodiment, the welding protrusion 303 is a solder protrusion or comprises a metal bump and a solder protrusion disposed on the top surface of the metal bump. In some embodiments, the material of the connection pad and metal bump is one or more of aluminum, nickel, tin, tungsten, platinum, copper, titanium, chromium, tantalum, gold, and silver, and the material of the solder protrusion is one or more of tin, tin-silver, tin-lead, tin-silver-copper, tin-silver-zinc, tin-zinc, tin-bismuth-indium, tin-indium, tin-gold, tin-copper, tin-zinc-indium, or tin-silver-antimony. When the first chip 301 and second chip 302 are mounted on the upper surface of the substrate 101, the back surfaces of the first chip 301 and second chip 302 are mounted on the upper surface of the substrate 101. In a specific embodiment, the back surface of the first chip 301 and the back surface of the second chip 302 are mounted on the upper surface of the substrate 101 by an adhesive glue, respectively.

Referring to FIG. 2, a light sensor 202 having a light window 203 is provided, the light sensor 202 having a light window 203 is mounted on the second chip 302, and the light sensor 202 having a light window 203 is electrically connected with the second chip 302.

The light sensor 202 is used for sensing light signals to generate electrical signals, the light sensor 202 may be a MEMS light sensor. The light window 203 serves as a window for light signal 12 (referring to FIG. 4) incident on the light-sensing area of the light sensor 202, and the light-sensing area senses the incident light to generate an electrical signal.

In an embodiment, the light sensor 202 comprises an opposing back surface and a light-sensing surface, the light-sensing surface comprising a middle area and an edge area surrounding the middle area, the middle area having a light-sensing area, the light window 203 being mounted on the surface of the edge area of the light-sensing surface by a first sealant 204, a sealed cavity being formed between the lower surface of the light window 203 and the light-sensing surface, on the back surface of the light sensor 202, there is a connection pad (not shown in the figures), the connection pad is electrically connected with the light-sensing area, and electrical signals sensed by the light-sensing area can be transmitted to the connection pad. When the light sensor 202 having a light window 203 is mounted on the second chip 302, the connection pad on the back of the light sensor 202 is soldered with the welding protrusion 303 on the active surface of the second chip 302 to achieve an electrical connection between the two. In an embodiment, between the back surface of the light sensor 202 and the active surface of the second chip 302, a bottom filler layer 304 may also be filled to provide a protective effect on the connection solder joints between the light sensor 202 and the second chip 302, and to reduce the problem of mismatch of the coefficients of thermal expansion between the light sensor 202 and the second chip 302, and to improve the accuracy and reliability of light sensor 202 detection. The material of the bottom filler layer 304 may be a silicone-based resin material, a thermoplastic resin material, a thermo-cured resin material, or a UV-cured resin material, and the formation process of the bottom filler layer comprises a dispensing process.

In an embodiment, the sealed cavity is filled with nitrogen gas, and the pressure in the sealed cavity is 0.2 times to 1 times atmospheric pressure. On the one hand, the dryness of the sealed cavity is maintained to prevent the influence of excessive humidity on the detection accuracy of the light sensor 202, and improve the service life, and on the other hand, since there will be a thermal process (e.g., a curing process or reflowing process) in the subsequent package process, the presence of nitrogen gas in the sealed cavity can reduce the risk of gas expansion and improve the structural stability of the light sensor 202.

In an embodiment, the first sealant 204 is a sealant containing a filler. The filler may be an organic filler or an inorganic filler.

In an embodiment, the process of mounting the light window 203 on the surface of the edge area of the light-sensing surface of the light sensor 202 comprises: fixing the light sensor 202 on a base in a processing chamber; heating the base to 40 degrees Celsius-50 degrees Celsius, which is conducive to maintaining the dryness of the subsequently formed sealed cavity; evacuating the processing chamber; after evacuating, filling the processing chamber with nitrogen gas to adjust the air pressure of the processing chamber to 0.2 times to 1 times atmospheric pressure, after this, dotting a first sealant 204 on the surface of the edge area of the light-sensing surface of the light sensor 202; and placing the light window 203 on the first sealant 204 to form a sealed cavity between the light window 203 and the light-sensing surface. It is noted that, in an embodiment, when the first sealant 204 is a sealant containing a filler, the first sealant is dotted directly. In another embodiment, when the first sealant 204 does not contain a filler, >4 adhesive points are dotted and cured, and then 1 turn of sealant is dotted.

In an embodiment, the light window 203 is a glass that transmits light, and in order to increase the light transmittance of the light window 203, the upper and lower surfaces of the light window 203 have a coating, the area where the lower surface of the light window 203 contacts the first sealant 204 is not coated, and the area is roughened by hacking to increase the bonding force of the first sealant 204 with the light window 203 to increase the sealing performance.

Referring to FIG. 3, a first lead wire 106 electrically connects the acoustic sensor 201 with the first chip 301, a second lead wire 107 electrically connects the first chip 301 with the substrate 101, and a third lead wire 108 electrically connects the second chip 302 with the substrate 101 are formed.

In a specific embodiment, the first lead wire 106 electrically connects a portion of the external connection pad of the acoustic sensor 201 with a portion of the connection pad on the first chip 301, and the second lead wire 107 electrically connects a portion of the connection pad on the first chip 301 with a portion of the upper pad 102 on the upper surface of the substrate 101, and the third lead wire 108 electrically connects a portion of the connection pad on the second chip 302 with a portion of the upper pad 102 on the upper surface of the substrate 101.

The materials of the first lead wire 106, the second lead wire 107, and the third lead wire 108 may be one or more of gold, aluminum, copper, silver, nickel, or palladium, and the process for forming the first lead wire 106, the second lead wire 107 and the third lead wire 108 comprises a lead wire bonding process or a wire bonding process (Wire Bonding, WB).

In an embodiment, after the first lead wire 106, the second lead wire 107, and the third lead wire 108 are formed, a second sealant 110 is formed to seal the side of the light sensor 202 having a light window 203 with the second chip 302 to further improve waterproofing performance and sealing performance of the light window 203, and a third sealant 109 is formed to seal the first chip 301 to improve the insulating performance and waterproofing performance of the first chip 301, the first lead wire 106, the second lead wire 107, and the third lead wire 108.

Referring to FIG. 4, a sound shielding cover 206 is provided, the sound shielding cover 206 having sound transmission holes 207 running through an inner sidewall surface and an outer sidewall surface of the sound shielding cover 206; and the sound shielding cover 206 is mounted on the upper surface of the substrate 101 such that the sound shielding cover 206 covers the acoustic sensor 201 and the first chip 301.

The sound shielding cover 206 is used to shield other electromagnetic interference on the acoustic sensor 201 and to enable the sound signal 11 (the frequency of the sound is 20 Hz-20,000 Hz) to be transmitted through the sound transmission holes 207 into the interior of the sound shielding cover 206 and to be received by the acoustic sensor 201.

In an embodiment, the thickness of the sound shielding cover 206 is less than or equal to 0.2 mm, the material of the sound shielding cover 206 is metal, and the surface of the sound shielding cover 206 is plated with nickel-gold (NiAu), which can be used for dust prevention.

In an embodiment, the sound shielding cover 206 is in an inverted “U” shape, and the sound shielding cover 206 is mounted on the upper surface of the substrate 101 by adhesive.

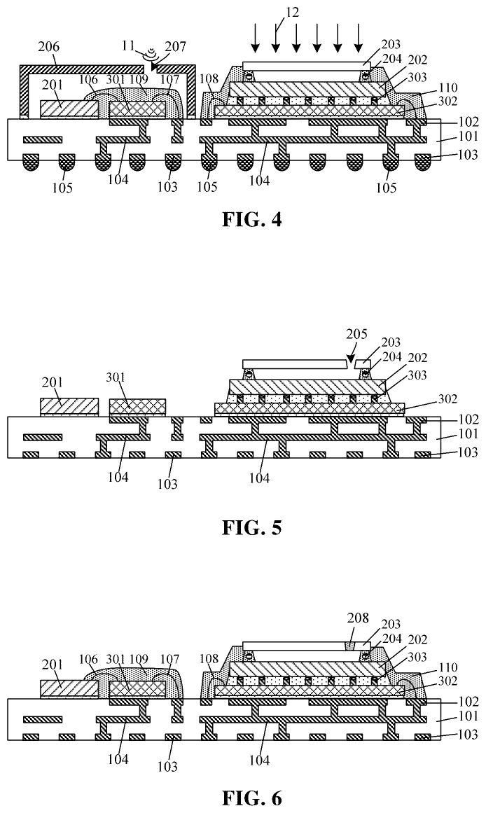

Another embodiment of the present disclosure also provides a method for forming a multi-sensor package structure, with reference to FIGS. 5-7, the main difference between the present embodiment (the embodiment shown in FIGS. 5-7) and the aforementioned embodiment (the embodiment shown in FIGS. 1-4) lies in that in the present embodiment, the light window 203 has at least one light window hole 205 (referring to FIG. 5) that runs through the upper and lower surfaces of the light window 203, and the light window hole 205 communicates with the sealed cavity, and after forming the second sealant 110, a fourth sealant 208 (referring to FIG. 6 and FIG. 7) is used to seal the light window hole 205. Whereas in the aforementioned embodiments, no light window hole is formed in the light window 203. It should be noted that, the definition or description of the same or similar parts of the present embodiment (the embodiment shown in FIGS. 5-7) and the aforementioned embodiment (the embodiment shown in FIGS. 1-4) will not be repeated in the present embodiment, and please refer to the definition or description of the corresponding parts of the aforementioned embodiment for details.

In the present embodiment, referring to FIG. 5, the function of the light window 203 having at least one light window hole 205 running through the upper and lower surfaces of the light window 203 is: on the one hand, the light window hole 205 can discharge the expansion gas generated during the reflow process or the curing process in the cavity between the light window 203 and the light-sensing surface of the light sensor 202, preventing the expansion of the gas from affecting or impairing the structural stability of light sensor 202; on the other hand, the light window hole 205 can discharge the volatile substances generated during the curing of the first sealant 204, preventing the volatile substances from remaining in the cavity and damaging the light sensor 202; furthermore on the other hand, the subsequent sealing of the light window hole 205 by the fourth sealant 208 (referring to FIG. 6 and FIG. 7) still enables a sealed cavity to be formed between the lower surface of the light window 203 and the light-sensing surface of the light sensor 202, such that the sealed cavity is filled with nitrogen gas, and the pressure in the sealed cavity is 0.2 times to 1 times the atmospheric pressure, so as to maintain the dryness of the sealed cavity, and to prevent the influence of excessive humidity on the detection accuracy of the light sensor 202.

In an embodiment, the light window holes 205 are provided at the edges or at the corners of the sealed cavity to avoid affecting the light path.

In an embodiment, the number of the light window holes 205 may be a pair, facilitating convection and venting, and reducing particle residue in the cavity.

Referring to FIG. 6, a fourth sealant 208 is used to seal the light window hole 205 after forming the second sealant 110 and the third sealant 109 (referring to FIG. 5). In an embodiment, the process of sealing the light window hole 205 using the fourth sealant 208 comprises: placing the package structure in a processing chamber, evacuating the processing chamber; after evacuating, filling the processing chamber with nitrogen gas to adjust the air pressure in the processing chamber to 0.2×-1× atmospheric pressure, and then dotting the fourth sealant 208 into the light window hole 205 to seal it, forming the sealed cavity.

Referring to FIG. 7, a sound shielding cover 206 is provided, the sound shielding cover 206 having sound transmission holes 207 running through an inner sidewall surface and an outer sidewall surface of the sound shielding cover 206; and the sound shielding cover 206 is mounted on the upper surface of the substrate 101, such that the sound shielding cover 206 covers the acoustic sensor 201 and the first chip 301.

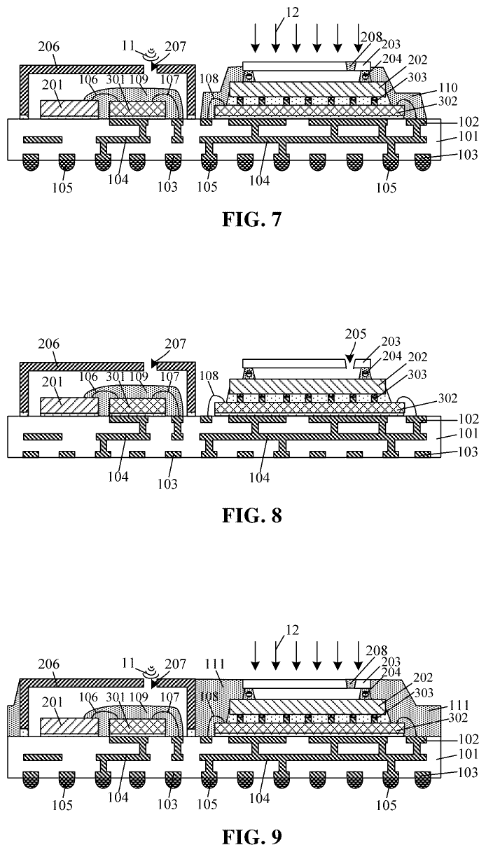

Another embodiment of the present disclosure also provides a method for forming a multi-sensor package structure, referring to FIGS. 8-9. The main difference between the present embodiment (the embodiment shown in FIGS. 8-9) and the aforementioned embodiment (the embodiment shown in FIGS. 5-7) lies in that: in the present embodiment, referring to FIG. 8, after the first lead wire 106, the second lead wire 107, and the third lead wire 108 are formed, a third sealant 109 that seals the first chip 301 is formed; the sound shielding cover 206 is mounted on the upper surface of the substrate 101; referring to FIG. 9, an integral sealant 111 is formed for sealing the side of the light sensor 202 having light window 203, the side of the second chip 302, and the side of the sound shielding cover 206; after the integral sealant 111 is formed, a fourth sealant 208 is used for sealing the light window hole 205, such that a sealed cavity is formed between the lower surface of the light window 203 and the light-sensing surface of the light sensor 202, so that the sealed cavity is filled with nitrogen gas, and the pressure in the sealed cavity is to be 0.2 times to 1 times atmospheric pressure.

In the present embodiment, the functions of forming the integral sealant 111 include enhancing the overall strength, air-tight performance, and waterproof performance of the package structure.

In an embodiment, after forming the integral sealant 111, the process of sealing the light window hole 205 with a fourth sealant 208 comprises: placing the package structure in a processing chamber, evacuating the processing chamber; after evacuating, filling the processing chamber with nitrogen gas to adjust the air pressure of the processing chamber to 0.2 times to 1 times atmospheric pressure, and then dabbing a fourth sealant 208 into the light window hole 205 for sealing, forming the sealed cavity.

An embodiment of the present disclosure also provides a multi-sensor package structure, referring to FIG. 4, comprising: a substrates 101; an acoustic sensor 201, a first chip 301, and a second chip 302 are mounted on the upper surface of the substrate 101; a light sensor 202 having a light window 203 and mounted on the second chip 302, the light sensor 202 having a light window 203 being electrically connected with the second chip 302; a first lead wire 106 electrically connecting the acoustic sensor 201 with the first chip 301, a second lead wire 107 electrically connecting the first chip 301 with the substrate 101, and a third lead wire 108 electrically connecting the second chip 302 with the substrate 101; a sound shielding cover 206 mounted on the upper surface of the substrate 101, the sound shielding cover 206 covers the acoustic sensor 201 and the first chip 301, the sound shielding cover 206 having sound transmission holes 207 running through the inner sidewall surface and the outer sidewall surface of the sound shielding cover 206.

In an embodiment, the acoustic sensor 201 is used for sensing sound signal 11 to generate an electrical signal, the first chip 301 is used for processing the electrical signal generated by sensing the acoustic sensor 201, the light sensor 202 is used for sensing light signal 12 to generate an electrical signal, the second chip 302 is used for processing the electrical signal generated by sensing of the light sensor 202.

In an embodiment, the acoustic sensor 201 comprises an opposing back surface and a sound-sensing surface, the sound-sensing surface having a suspended sound-sensing film, the first chip 301 and the second chip 302 both comprising an opposing back surface and an active surface, respectively, and the back surface of the acoustic sensor 201, the back surface of the first chip 301, and the back surface of the second chip 302 are mounted on the upper surface of the substrate 101 by an adhesive, respectively.

In an embodiment, the light sensor 202 comprises an opposing back surface and a light-sensing surface, the back surface being to be electrically connected, the light-sensing surface comprising a middle area and an edge area surrounding the middle area, the middle area having a light-sensing area, the light window 203 being mounted on the surface of the edge area of the light-sensing surface by a first sealant 204, and a sealed cavity being formed between the lower surface of the light window 203 and the light-sensing surface.

In an embodiment, the first sealant 204 is a sealant containing a filler.

In an embodiment, the upper and lower surfaces of the light window 203 have a coating, and the area of the lower surface of the light window 203 in contact with the first sealant 204 is uncoated, and the area is roughened by hacking.

In an embodiment, the sealed cavity is filled with nitrogen gas, and the pressure in the sealed cavity is to be 0.2 times to 1 times atmospheric pressure.

In an embodiment, referring to FIG. 4 or FIG. 7, it further comprises a second sealant 110 sealing the side of the light sensor 202 having a light window 203 and the second chip 302, and a third sealant 109 sealing the first chip 301.

In an embodiment, referring to FIG. 9, it further comprises a third sealant 109 sealing the first chip 301; and an integral sealant 111 sealing the sides of the light sensor 202 having a light window 203, the second chip 302, and the sides of the sound shielding cover 206.

In an embodiment, referring to FIG. 7 or FIG. 9, the light window 203 has at least one light window hole 205 (referring to FIG. 5 or FIG. 8) running through the upper and lower surfaces of the light window 203, and a fourth sealant 208 sealing the light window hole 205.

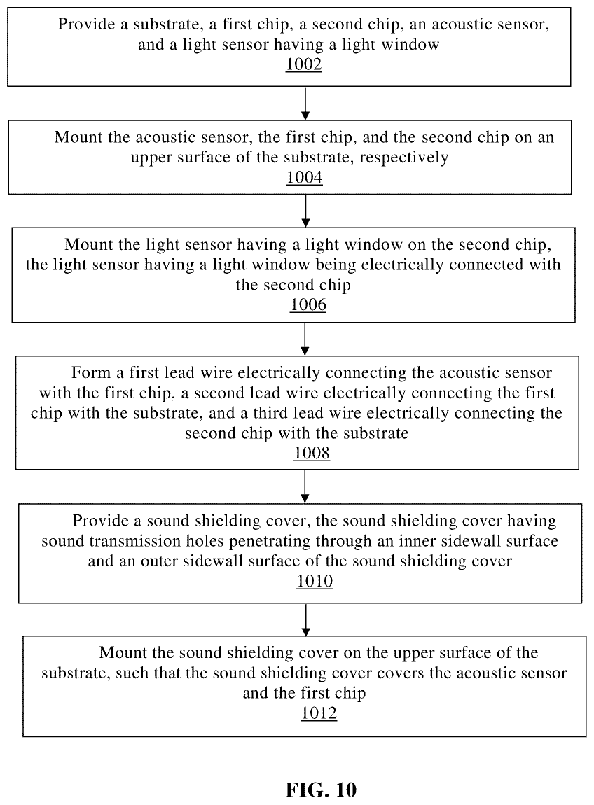

FIG. 10 is a flow chart of a method for forming a multi-sensor package structure in an embodiment of the present disclosure.

At operation 1002, a substrate 101, a first chip 301, a second chip 302, an acoustic sensor 201, and a light sensor 202 having a light window 203 are provided. At operation 1004, the acoustic sensor 201, the first chip 301, and the second chip 302 are mounted on an upper surface of the substrate 101, respectively. At operation 1006, the light sensor 202 having the light window 203 is mounted on the second chip 302. The light sensor has the light window 203 electrically connected with the second chip 302. At operation 1008, a first lead wire 106 electrically connecting the acoustic sensor 201 with the first chip 301 is formed, a second lead wire 107 electrically connecting the first chip 301 with the substrate 101 is formed, and a third lead wire 108 electrically connecting the second chip 302 with the substrate 101 is formed. At operation 1010, a sound shielding cover 206 is provided. The sound shielding cover 206 has sound transmission holes 207 penetrating through an inner sidewall surface and an outer sidewall surface of the sound shielding cover 206. At operation 1012, the sound shielding cover i206 s mounted on the upper surface of the substrate 101, such that the sound shielding cover 206 covers the acoustic sensor 201 and the first chip 301.

It should be noted that the portions of the present embodiment (multi-sensor package structure) that are the same or similar to the aforementioned embodiment (method for forming a multi-sensor package structure) will not be repeated in the present embodiment, and please refer to the definition or description of the corresponding parts of the aforementioned embodiment for details.

Although the present disclosure has been disclosed as above with embodiments, they are not intended to limit the present disclosure, and any person skilled in the art can make possible changes and modifications to the technical solutions of the present disclosure by utilizing the above-disclosed methods and technical contents without departing from the spirit and scope of the present disclosure. Therefore, any simple modifications and equivalent changes and embellishments to the above embodiments in accordance with the technical substance of the present disclosure, without departing from the technical solutions of the present disclosure, are within the scope of protection of the technical solutions of the present disclosure.

What is claimed is:

1. A method for forming a multi-sensor package structure, comprising:
providing a substrate, a first chip, a second chip, an acoustic sensor, and a light sensor having a light window;
mounting the acoustic sensor, the first chip, and the second chip on an upper surface of the substrate, respectively;
mounting the light sensor having the light window on the second chip, the light sensor having the light window electrically connected with the second chip;
forming a first lead wire electrically connecting the acoustic sensor with the first chip, a second lead wire electrically connecting the first chip with the substrate, and a third lead wire electrically connecting the second chip with the substrate;
providing a sound shielding cover, the sound shielding cover having sound transmission holes penetrating through an inner sidewall surface and an outer sidewall surface of the sound shielding cover; and
mounting the sound shielding cover on the upper surface of the substrate, such that the sound shielding cover covers the acoustic sensor and the first chip.

2. The method according to claim 1, wherein the acoustic sensor is configured to sense sound signals to generate electrical signals, the first chip is configured to process the electrical signal generated by the sensing of the acoustic sensor, the light sensor is configured to sense a light signal to generate an electrical signal, and the second chip is configured to process the electrical signal generated by the sensing of the light sensor.

3. The method according to claim 1, wherein the acoustic sensor comprises an opposing back surface and a sound-sensing surface, the sound-sensing surface having a suspended sound-sensing film, the first chip and the second chip both comprising an opposing back surface and an active surface, respectively, and the back surface of the acoustic sensor, the back surface of the first chip, and the back surface of the second chip being mounted on an upper surface of the substrate by an adhesive glue, respectively.

4. The method according to claim 1, wherein the light sensor comprises an opposing back surface and a light-sensing surface, the light-sensing surface comprising a middle area and an edge area surrounding the middle area, the middle area having a light-sensing area therein, the light window being mounted on the surface of the edge area of the light-sensing surface by a first sealant, and a sealed cavity is formed between the lower surface of the light window and the light-sensing surface.

5. The method according to claim 4, wherein
the first sealant is a filler-containing sealant; and
a temperature of a base for securing the light sensor is heated to 40 degrees Celsius to 50 degrees Celsius when the light window is mounted to the surface of the edge area by the first sealant.

6. The method for according to claim 4, wherein the upper and lower surfaces of the light window have a coating, and the area of the lower surface of the light window in contact with the first sealant is uncoated and the area is roughened by hacking.

7. The method according to claim 4, wherein after forming the first lead wire, the second lead wire, and the third lead wire, a second sealant is formed that seals the side of the light sensor having a light window and the second chip, and a third sealant is formed that seals the first chip.

8. The method according to claim 7, wherein
after forming the first lead wire, the second lead wire, and the third lead wire, a third sealant is formed that seals the first chip;
the sound shielding cover is mounted on the upper surface of the substrate; and
an integral sealant is formed that seals the side of the light sensor having a light window, the second chip, and the side of the sound shielding cover.

9. The method according to claim 8, wherein the sealed cavity is filled with nitrogen gas, and a pressure in the sealed cavity is 0.2 times to 1 times atmospheric pressure.

10. The method according to claim 9, wherein the light window has at least one light window hole in the light window running through the upper and lower surfaces of the light window, the light window hole being in communication with the sealed cavity, and a fourth sealant is employed to seal the light window hole after forming the second sealant or after forming the integral sealant.

11. The method according to claim 10, wherein sealing the light window hole with a fourth sealant comprises:
placing the multi-sensor package structure in a processing chamber;
evacuating the processing chamber;
after evacuating, filling the processing chamber with nitrogen gas to adjust an air pressure of the processing chamber to 0.2 times to 1 times atmospheric pressure; and
dabbing a fourth sealant into the light window hole for sealing.

12. A multi-sensor package structure, comprising:
a substrate;
an acoustic sensor, a first chip, and a second chip mounted on an upper surface of the substrate;
a light sensor having a light window mounted on the second chip, the light sensor having a light window being electrically connected with the second chip;
a first lead wire electrically connecting the acoustic sensor with the first chip, a second lead wire electrically connecting the first chip with the substrate, and a third lead wire electrically connecting the second chip with the substrate; and
a sound shielding cover mounted on the upper surface of the substrate, the sound shielding cover covering the acoustic sensor and the first chip, the sound shielding cover having sound transmitting holes running through an inner sidewall surface and an outer sidewall surface of the sound shielding cover.

13. The multi-sensor package structure according to claim 12, wherein the acoustic sensor is configured to sense sound signals to generate electrical signals, the first chip is configured to process the electrical signals generated by the sensing of the acoustic sensor, the light sensor is configured to sense light signals to generate electrical signals, and the second chip is configured to process the electrical signals generated by the sensing of the light sensor.

14. The multi-sensor package structure according to claim 12, wherein the acoustic sensor comprises an opposing back surface and a sound-sensing surface, the sound-sensing surface having a suspended sound-sensing film, the first chip and the second chip both comprising an opposing back surface and an active surface, respectively, and the back surface of the acoustic sensor, the back surface of the first chip, and the back surface of the second chip being mounted on an upper surface of the substrate by an adhesive glue, respectively.

15. The multi-sensor package structure according to claim 12, wherein the light sensor comprises an opposing back surface and a light-sensing surface, the light-sensing surface comprising a middle area and an edge area surrounding the middle area, the middle area having a light-sensing area therein, the light window being mounted on the surface of the edge area of the light-sensing surface by a first sealant, and a sealed cavity is formed between the lower surface of the light window and the light-sensing surface.

16. The multi-sensor package structure according to claim 15, wherein the first sealant is a filler-containing sealant.

17. The multi-sensor package structure according to claim 15, wherein the upper and lower surfaces of the light window have a coating, and the area of the lower surface of the light window in contact with the first sealant is uncoated and the area is roughened by hacking.

18. The multi-sensor package structure according to claim 15, further comprising a second sealant sealing the side of the light sensor having a light window and the second chip, and a third sealant sealing the first chip.

19. The multi-sensor package structure according to claim 15, further comprising:
a third sealant sealing the first chip; and
an integral sealant sealing the side of the light sensor having a light window, the second chip, and the side of the sound shielding cover.

20. The multi-sensor package structure according to claim 18, wherein the sealed cavity is filled with nitrogen gas, a pressure in the sealed cavity being 0.2 times to 1 times atmospheric pressure.
